(19) United States
(12) Patent Application Publication
(10) Pub. No.: US 2014/0357009 A1
(43) Pub. Date: Dec. 4, 2014

(54) Process For Manufacturing A Photovoltaic Cell

(71) Applicant: COMMISSARIAT A L'ENERGIE ATOMIQUE ET AUX ENERGIES ALTERNATIVES, Paris (FR)

(72) Inventors: Bertrand Paviet-Salomon, Lyon (FR); Samuel Gall, Arradon (FR); Adeline Lanterne, Saint Front D'Alemps (FR); Sylvain Manuel, Montgardin (FR)

(21) Appl. No.: 14/368,637

(22) PCT Filed: Dec. 19, 2012
(86) PCT No.: PCT/FR2012/052985

§ 371 Date: Jun. 25, 2014

(30) Foreign Application Priority Data
Jan. 5, 2012 (FR) 1250105

(51) Int. Cl. H01L 31/18; H01L 31/0288

(52) U.S. Cl. CPC H01L 31/1864; H01L 31/0288
USPC 438/57

(57) ABSTRACT

A method of manufacturing a photovoltaic cell including forming a semiconductor substrate comprising opposite first and second surfaces; forming, on the first surface of the substrate, a first semiconductor area doped by implantation of first dopant elements across the substrate thickness and by thermal activation of the first implanted dopant elements at a first activation temperature; forming, on the second surface of the substrate, a second semiconductor area doped by implantation of second dopant elements across the substrate thickness and by thermal activation of the second implanted dopant elements at a second activation temperature lower than the first activation temperature; at least the thermal activation of the first dopant elements is performed by laser irradiation, the irradiation parameters being selected so that the radiation is absorbed at most down to a depth of the first micrometer of the substrate.

### FIELD OF THE INVENTION

The invention relates to the manufacturing of semiconductor microcomponents comprising two areas doped by implantation of dopants and thermal activations. The present invention more specifically applies to photovoltaic cells.

### BACKGROUND OF THE INVENTION

Schematically, a photovoltaic cell comprises a semiconductor substrate, usually made of doped silicon, for example, p-doped, covered on one of its surfaces, usually the front surface intended to receive the radiation, with a layer doped with an opposite doping, for example, an n-doped layer, thus forming a pn junction for the collection of the photocarriers generated by the cell illumination. The n layer is further covered with an antireflection layer to provide a good photon absorption, and electric contacts are provided in the n layer to collect the generated current.

To improve the cell efficiency, a heavily-doped area of the same doping type as the substrate, for example, a layer called “p⁺” due to its high p-type dopant concentration, is formed on the other surface of the substrate. This area is usually called “BSF” (“Back Surface Field”) area.

The n layer is for example formed by means of a step of POCl₃ gas diffusion at a temperature of 850-950° C. for several tens of minutes, as for example described in J. C. C. Tsai's document, “Shallow Phosphorus Diffusion Profiles in Silicon”, Proc. of the IEEE 57 (9), 1969, pp. 1499-1506, or by means of an ion implantation of phosphorus atoms, followed by a step of thermal activation of the implanted atoms, as for example described in D. L. Meier et al.'s document, “N-type, ion implanted silicon solar cells and modules”, Proc. 37^{th} PVSC, 2011.

The BSF layer is for example formed by depositing a screen printing paste containing aluminum over the entire rear surface of the substrate. Such a BSF layer, called “Al-BSF”, is then activated by anneal, for example, in a continuous furnace at a 885° C. temperature and with a 6,500 mm/min belt speed, as for example described in B. Sopori et al.'s document, “Fundamental mechanisms in the fire-through contact metallization of Si solar cells: a review”, 17th Workshop on Crystalline Silicon Solar Cells & Modules: Materials and Process, Vail, Colo., USA, Aug. 5-8, 2007).

The Al-BSF layer however raises two issues. First, the deposition of a screen printing paste all over the rear surface of the substrate causes a significant bow thereof during the anneal necessary to activate the AI-BSF layer, due to different thermal expansion coefficients between silicon and the screen printing paste. This effect is all the stronger as the different layers in presence are thin, which is highly prejudicial to a good module arrangement of photovoltaic cells manufactured in this way, as for example described in F. Huster's document, “Aluminum-Back surface field: bow investigation and elimination”, Proc. 20^{th} EUPVSEC, 2005. Then, due to the low solubility of aluminum in silicon, the desired field effect which justifies the forming of a BSF layer is low, which thus limits the efficiency gain provided by Al-BSF.

Various alternatives to Al-BSF have thus been studied to solve these problems. A method currently used thus comprises using a boron-based BSF layer, commonly called “B-BSF”, instead of the Al-BSF layer. A B-BSF layer may be formed similarly to the n area at the front surface of the substrate, for example, by means of a gas diffusion of BCl₃ or BBr₃ type, but also by means of a boron atom implantation, followed by a step of thermal activation of the implanted atoms.

It can thus be envisaged to form a photovoltaic cell by using a phosphorus ion implantation for the n layer and a boron ion implantation for the B-BSF. The problem of such a cell is that the temperatures of the thermal anneal necessary to activate the implanted atoms are very different for boron and phosphorus. Thus, for phosphorus, temperatures lower than 850° C. are necessary, while boron requires temperatures higher than 1,000° C. to be activated. To overcome this issue, the two ion implantations and their two respective thermal anneals are carried out separately. First, boron is implanted on the rear surface of the substrate to obtain the BSF layer, after which the assembly thus obtained is annealed at 1,000° C. Then, phosphorus is implanted at the front surface and the obtained assembly is then annealed at 850° C., the boron being not or only slightly impacted by this “low temperature” step. D. L. Meier's document, mentioned hereabove, may for example be consulted for further detail.

The implementation of separate implantation and thermal anneal steps however has a number of disadvantages. Particularly, the ion implantation steps generally require being performed under vacuum and in a clean room to limit contamination risks. Such a separate implementation, induced by the incompatibility of thermal activation temperatures, thus implies breaking the vacuum at least once and imposes multiplying photovoltaic cell manipulations during the most critical phases, in terms of contamination, of their manufacturing.

Further, the implementation of a thermal anneal at very high temperature (greater than 1,000° C. as required for the activation of boron) applies to the entire substrate and generates a degradation of the general bulk lifetime of the substrate.

### SUMMARY OF THE INVENTION

One of the aims of the present invention is to provide a method of manufacturing a photovoltaic cell having its two surfaces doped by ion implantation and thermal activation, which minimizes the manufacturing constraints induced by the different thermal activation temperatures, and particularly which enables not to have totally separate implantations and activations in case of a temperature incompatibility.

Another aim of the invention is to provide a method which does not alter the substrate lifetime.

For this purpose, the invention aims at a method of manufacturing a photovoltaic cell comprising:
forming a semiconductor substrate comprising opposite first and second surfaces;
forming, on the first surface of the substrate, a first semiconductor area doped by implantation of first dopant elements across the substrate thickness and by thermal activation of the first implanted dopant elements at a first activation temperature;
forming, on the second surface of the substrate, a second semiconductor area doped by implantation of second dopant elements across the substrate thickness and by thermal activation of the second implanted dopant elements at a second activation temperature lower than the first activation temperature.

According to the invention, the substrate has a thickness greater than 50 micrometers, and at least the thermal activation of the first dopant elements is performed by laser irradiation, the irradiation parameters being selected so that the radiation is absorbed at most down to a depth corresponding to the first micrometer of the substrate.

In other words, the laser irradiation allows an intense local temperature rise of the irradiated surface (down to a depth in the order of the depth of absorption of the radiation in the substrate, that is, in the order of one micrometer), thus causing the thermal activation of the dopant elements implanted in the irradiated surface. Further, the irradiation is local and the substrate dissipates heat, so that the surface opposite to the irradiated surface is submitted to no or very little heating. It is thus possible to implant in this other surface dopant elements without for the latter to be submitted to too significant a heating. It is thus possible to implant boron atoms on a surface of the substrate and phosphorus atoms on the other surface of the substrate, and to irradiate with a laser the surface implanted with boron atoms without for the surface implanted with phosphorus atoms to be submitted to an excessive heating.

According to an embodiment, the thermal activations are carried out once the ion implantations have been completed. Particularly, the ion implantations are performed in a same vacuum enclosure, so that the vacuum is not broken between the carrying out thereof. As a variation, the ion implantations are performed prior to the thermal activations. The ion implantation of elements may for example be directly followed by the thermal activation thereof.

According to an embodiment, the thermal activation of the second dopant elements is performed by thermal anneal. As a variation, the thermal activation may also be performed by laser irradiation, particularly an irradiation step separate from the irradiation step activating the first elements.

According to an embodiment, the first dopant elements are boron atoms, and the second dopant elements are phosphorus atoms.

According to an embodiment, the laser irradiation of the first surface is performed with a pulsed laser having a wavelength in the range from 150 nm to 600 nm, and having a surface power density in the range from 1 to 7 J/cm² with a pulse duration in the range from 10 nanoseconds to 1 microsecond. Such an irradiation enables to obtain a high temperature (in the order of 1,000° C. and beyond) down to a depth smaller than one micrometer.

Particularly, the laser irradiation of the first surface comprising implanted boron atoms is an irradiation by means of a pulsed laser having a fluence in the order of 3 J/cm² and a duration in the order of 150 nanoseconds. Such a laser irradiation particularly enables to obtain a heating greater than 1,000° C. for the thermal activation of the boron atoms implanted in one of the substrate surfaces.

According to an embodiment, the substrate, particularly made of silicon, has a thickness in the range from 50 micrometers to 300 micrometers, and preferably a thickness of 180 micrometers.

According to an embodiment, the substrate is a p-doped semiconductor substrate, the first semiconductor area being an n doped area and the second semiconductor area being a p doped area.

As a variation, the substrate is an n-doped semiconductor substrate, the first semiconductor area being an n doped area and the second semiconductor area being a p doped area.

### BRIEF DESCRIPTION OF THE DRAWINGS

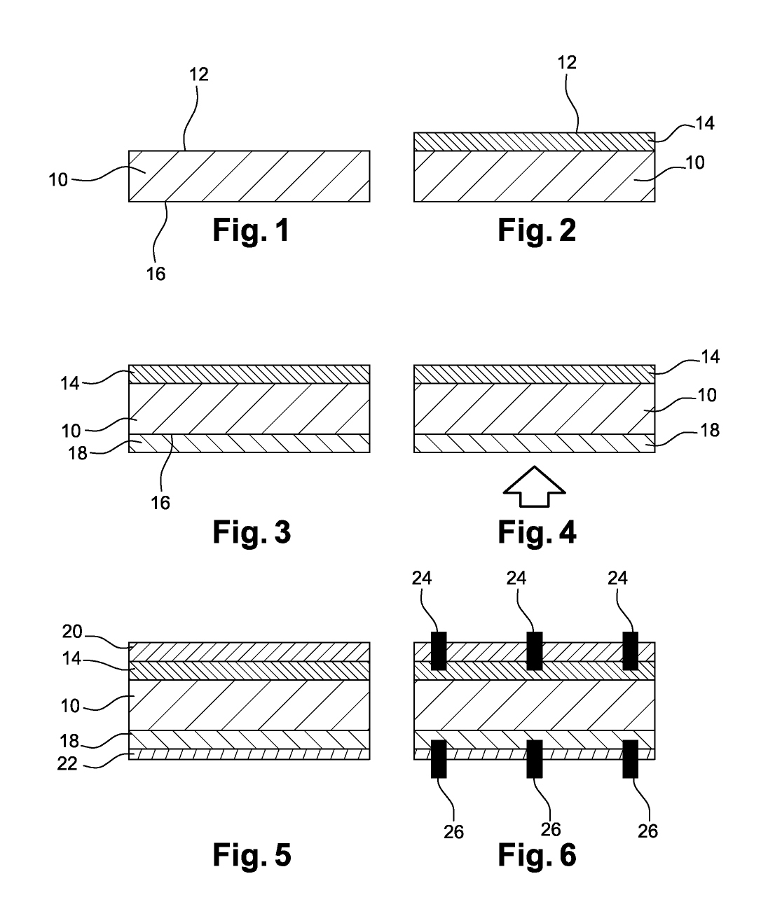

The invention will be better understood on reading of the following description provided as an example only in relation with the accompanying drawings, where the same reference numerals designate the same or similar elements and where FIGS. 1 to 6 are simplified cross-section views illustrating a method of manufacturing a photovoltaic cell according to the invention.

### DETAILED DESCRIPTION OF THE INVENTION

Referring to FIGS. 1 to 6, a method of manufacturing a photovoltaic cell according to the invention starts with the forming of a p doped silicon substrate 10 (FIG. 1), having a thickness greater than 50 micrometers, particularly a thickness in the range from 50 micrometers to 300 micrometers, for example, 180 micrometers, optionally followed by the chemical texturing of one 12 of its surfaces, for example, by application of a 1% KOH solution at a 80° C. temperature for 40 min.

Surface 12 is intended to receive the radiation to be converted into current, and is called hereafter the “front” surface.

The method carries on with the ion implantation of phosphorus atoms in front surface 12 (FIG. 2), for example, a POCl₃-type implantation with a power in the range from 5 to 50 keV, for example, 30 keV and a dose in the range from 10¹⁴ at/cm² to 6.10¹⁵ at/cm², for example, 4.10¹⁵ at/cm² or a plasma immersion, as known per se in the state of the art, to obtain a phosphorus-implanted area 14 on front surface 12 with a typical thickness smaller than 100 nanometers.

Then, an ion implantation of boron atoms is performed in surface 16 or “rear” surface, opposite to front surface 12 (FIG. 3), for example, a BCl₃ or BBr₃-type implantation with a power in the range from 5 to 30 keV, for example, 10 keV, and a dose in the range from 10¹⁴ at/cm² to 5.10¹⁵ at/cm², for example, 3.10¹⁵ at/cm² or a plasma immersion, as known per se in the state of the art, to obtain a boron-implanted area 18 on rear surface 16 with a typical thickness smaller than 100 nanometers.

Preferably, the phosphorus and boron ion implantations are carried ou in the same vacuum enclosure of an ion implantation device, which enables not to break the vacuum between these two implantations and thus minimizes the contamination risk.

The method then carries on with the laser irradiation of all or part of rear surface 16 with a laser to thermally activate and to diffuse in depth (typically, down to a depth smaller than 500 nanometers, for example, in the order of 200 nanometers) the boron atoms which are implanted therein, thus forming a B-BSF layer without damaging front surface 12 and the phosphorus atoms which are located therein (FIG. 4). The thermal activation of the first elements is advantageously performed by irradiating the entire rear surface 16 by means of a laser allowing such an irradiation, particularly for a very short time.

More particularly, the thermal activation of boron atoms at the rear surface is performed by means of a 308-nanometer pulsed excimer laser, with pulse durations equal to 150 nanoseconds, pulsed at 200 kHz and having an energy density or fluence equal to 3 J/cm², which enables to locally reach a temperature greater than 1,000° C. It will be within the abilities of those skilled in the art to adapt the irradiation parameters according to the available laser, it being sufficient for the radiation to be absorbed across a thickness or depth smaller than one micrometer, and advantageously smaller than 500 or 300 nanometers, and for the heating to remain in the order of 1,000° C. (and in any case not to damage the material).

Typically, the laser irradiation may be performed with a pulsed laser having a wavelength in the range from 150 nanometers to 600 nanometers, and having a surface power density in the range from 1 to 7 J/cm² with a pulse duration in the range from 10 nanoseconds to 1 microsecond, and a pulse rate in the range from 1 kHz to 1 GHz.

The thermal activation of the phosphorus atoms implanted in front surface 12 is then carried out (FIG. 5), preferably by thermal anneal at 840° C. in an oxidation tube, or by laser irradiation, or by rapid thermal processing (or RTP anneal).

An antireflection layer 20, also having a passivation function, is then deposited on front surface 12 of the cell, for example, a layer having a 75-nanometer thickness of SiNₓ deposited by PECVD (“Plasma Enhanced Chemical Vapor Deposition”) of 440-kHz frequency at a 450° C. temperature.

A passivation layer 22 is also deposited on rear surface 16, for example, a layer having a 15-nanometer thickness of SiNₓ deposited by PECVD of 440-kHz frequency at a 450° C. temperature.

Finally, front surface contacts 24 and rear surface contacts 26, advantageously in the form of grids, are formed on front surface 12 and rear surface 16 of the cell, after which said contacts 24, 26 are annealed (FIG. 6).

For example, a metallization by screen printing of the front surface is performed with a silver paste deposited on a mask comprising a network of openings of 70 micrometers with a 2.1-millimeter pitch, and a metallization of the rear surface is performed with an aluminum paste deposited on a mask comprising openings of 70 micrometers with a 1-millimeter pitch, after which the front surface and rear surface contacts are annealed in a Centrotherm-type infrared furnace, with a temperature in the range from 850 to 1,050° C. at a speed in the range from 2,000 to 6,500 mm/min.

An application of the invention to the forming of a photovoltaic cell having a p-type substrate has been described. The method also applies to a photovoltaic cell having an n-type substrate for the manufacturing of a so-called “inverted n-type” cell. In this case, the doped semiconductor area located at the rear surface, and containing boron, behaves as an emitter, while the front surface doped semiconductor area containing phosphorus is a so-called FSF (“Front Surface Field”) layer which plays, for the front surface, a role equivalent to that of a rear surface BSF layer.

The invention also applies to the forming of a standard n-type structure, that is, comprising p-type emitters at the front surface, formed by means of a boron implantation followed by the thermal activation by laser irradiation such as previously described, and forming a rear-surface implanted phosphorus BSF layer obtained by conventional implantation and thermal activation, or a conventional implantation and an activation by laser irradiation.

The method according to the invention also applies to the forming of a selective front surface emitter for photovoltaic cells with a p-type substrate, or to a selective FSF layer in the case of inverted n-type cells, and/or a local BSF layer at the rear surface of photovoltaic cells.

1. A method for manufacturing a photovoltaic cell comprising:
forming a semiconductor substrate comprising opposite first and second surfaces;
forming, on the first surface of the substrate, a first semiconductor area doped by implantation of first dopant elements across the substrate thickness and by thermal activation of the first implanted dopant elements at a first activation temperature;
forming, on the second surface of the substrate, a second semiconductor area doped by implantation of second dopant elements across the substrate thickness and by thermal activation of the second implanted dopant elements at a second activation temperature lower than the first activation temperature;
wherein the substrate has a thickness greater than 50 micrometers, and wherein at least the thermal activation of the first dopant elements is performed by laser irradiation, the irradiation parameters being selected so that the radiation is absorbed at most down to a depth of the first micrometer of the substrate.

2. The photovoltaic cell manufacturing method of claim 1, wherein the thermal activations are performed once the ion implantations have been completed.

3. The photovoltaic cell manufacturing method of claim 1, wherein the thermal activation of the second dopant elements is performed by a thermal anneal or by a laser irradiation.

4. The photovoltaic cell manufacturing method of claim 1, wherein the first dopant elements are boron atoms, and wherein the second dopant elements are phosphorus atoms.

5. The photovoltaic cell manufacturing method of claim 1, wherein the laser irradiation of the first surface is a laser irradiation with a wavelength in the range from 150 nanometers to 600 nanometers.

6. The photovoltaic cell manufacturing method of claim 1, wherein the laser irradiation of the first surface comprising implanted boron atoms is an irradiation by pulsed laser having a fluence in the range from 1 to 7 J/cm² with a pulse duration in the range from 10 nanoseconds to 1 microsecond.

7. The photovoltaic cell manufacturing method of claim 1, wherein the substrate, has a thickness in the range from 50 micrometers to 300 micrometers.

8. The photovoltaic cell manufacturing method of claim 1, wherein the substrate is a p-doped semiconductor substrate, wherein the first semiconductor area is an n-doped area, and wherein the second semiconductor area is a p-doped area.

9. The photovoltaic cell manufacturing method of claim 1, wherein the substrate is an n-doped semiconductor substrate, wherein the first semiconductor area is an n-doped area, and wherein the second semiconductor area is a p-doped area.

10. The photovoltaic cell manufacturing method of claim 7, wherein the substrate is made of silicon.

11. The photovoltaic cell manufacturing method of claim 7, wherein the substrate has a thickness of 180 micrometers.
